(19) United States
(12) Patent Application Publication
(10) Pub. No.: US 2024/0213065 A1
(43) Pub. Date: Jun. 27, 2024

(54) METHOD FOR CALCULATING THROUGHPUT IN SEMICONDUCTOR MANUFACTURING APPARATUS, SEMICONDUCTOR MANUFACTURING APPARATUS, AND COMPUTER PROGRAM PRODUCT

(71) Applicant: EBARA CORPORATION, Tokyo (JP)

(72) Inventor: Shunsuke KAGAYA, Tokyo (JP)

(21) Appl. No.: 18/525,309

(22) Filed: Nov. 30, 2023

(30) Foreign Application Priority Data
Dec. 23, 2022 (JP) 2022-206434

(51) Int. Cl. H01L 21/67; G05B 19/418

(52) U.S. Cl. CPC H01L 21/67276; G05B 19/41835; G05B 2219/45031

(57) ABSTRACT

An object is to obtain a throughput of a semiconductor manufacturing apparatus precisely. A method for calculating a throughput in a semiconductor manufacturing apparatus, which comprises plural units, is provided, and the method comprises steps for: obtaining a process parameter relating to processing of a substrate in the semiconductor manufacturing apparatus; obtaining, from a memory, maintenance information with respect to each unit in the plural units, wherein the maintenance information comprises timing of maintenance of each unit in the plural units and the length of time required for the maintenance, wherein the maintenance is that planned to be performed in a period that ends when processing of the substrate in the semiconductor manufacturing apparatus is completed; and calculating a throughput of the semiconductor manufacturing apparatus, based on the process parameter and the maintenance information.

### TECHNICAL FIELD

The present invention relates to a method for calculating throughput in a semiconductor manufacturing apparatus, a semiconductor manufacturing apparatus, and a computer program product.

### BACKGROUND ART

One of indexes representing performance of a semiconductor manufacturing apparatus is throughput. The throughput is defined as the number of substrates which can be processed by a semiconductor manufacturing apparatus per unit time. The throughput can be used when making a production schedule in a semiconductor manufacturing factory, for example. Patent Literature 1 discloses a technique for calculating throughput and displaying it as an operation state in a semiconductor manufacturing apparatus.

### CITATION LIST

### Patent Literature

PTL 1: Japanese Patent Application Public Disclosure No. H10-135092

### SUMMARY OF INVENTION

### Technical Problem

When operating a semiconductor manufacturing apparatus, it is inevitable to perform maintenance such as replacing of components and so on. As a result that maintenance is performed, the rate of operation of the semiconductor manufacturing apparatus is lowered, and throughput is affected thereby.

Thus, it is desired to obtain, with high accuracy, throughput of a semiconductor manufacturing apparatus.

### Solution to Problem

(Mode 1) According to mode 1, a method for calculating a throughput in a semiconductor manufacturing apparatus, which comprises plural units, is provided, and the comprises steps for: obtaining a process parameter relating to processing of a substrate in the semiconductor manufacturing apparatus; obtaining, from a memory, maintenance information with respect to each unit in the plural units, wherein the maintenance information comprises timing of maintenance of each unit in the plural units and the length of time required for the maintenance, wherein the maintenance is that planned to be performed in a period that ends when processing of the substrate in the semiconductor manufacturing apparatus is completed; and calculating a throughput of the semiconductor manufacturing apparatus, based on the process parameter and the maintenance information.

(Mode 2) According to mode 2 that comprises the method in mode 1, the step for calculating a throughput of the semiconductor manufacturing apparatus comprises steps for: creating, based on the process parameter and the maintenance information, a timetable showing an operation schedule of the plural units; and calculating, based on the timetable, a throughput of the semiconductor manufacturing apparatus.

(Mode 3) According to mode 3 that comprises the method in mode 2, the method further comprises a step for updating, in association with progress in processing of the substrate in the semiconductor manufacturing apparatus, the maintenance information stored in the memory, wherein creating of the timetable is performed in response to occurrence of a predetermined event and based on the updated maintenance information at the time of occurrence of the event.

(Mode 4) According to mode 4 that comprises the method in mode 2, creating of the timetable comprises determining the operation schedule in such a manner that each of all units included in the maintenance information as objects of maintenance is not used during maintenance thereof.

(Mode 5) According to mode 5 that comprises the method in mode 1, the step for calculating a throughput of the semiconductor manufacturing apparatus comprises steps for: calculating, based on the process parameter, individual throughputs of the plural units; correcting, based on the maintenance information, the individual throughputs; and determining, based on the corrected individual throughputs, a throughput of the semiconductor manufacturing apparatus.

(Mode 6) According to mode 6 that comprises the method in mode 5, the method further comprises a step for updating, in association with progress in processing of the substrate in the semiconductor manufacturing apparatus, the maintenance information stored in the memory, wherein correcting of the individual throughputs is performed in response to occurrence of a predetermined event and based on the updated maintenance information at the time of occurrence of the event.

(Mode 7) According to mode 7 that comprises the method in mode 5, correcting of the individual throughputs comprises correcting the individual throughputs according to a ratio between the number of units which are objects of maintenance and the number of units which are not objects of maintenance.

(Mode 8) According to mode 8, a semiconductor manufacturing apparatus is provided, and the semiconductor manufacturing apparatus comprises: plural units; a computer constructed to calculate the throughput according to the method recited in any one of claims 1-7; and a display device for displaying the calculated throughput.

(Mode 9) According to mode 9, a computer program product comprising computer executable instructions is provided, and the computer executable instructions are those constructed to make a computer implement the method recited in any one of claims 1-7 when the computer executable instructions are executed by a processor in the computer.

### BRIEF DESCRIPTION OF DRAWINGS

FIG. 1 is a general layout drawing of a plating apparatus relating to an embodiment of the present invention.

FIG. 2 is a schematic cross-sectional side view of a plating module.

FIG. 3 is a configuration diagram of an example system used for implementing a method according to an embodiment of the present invention.

FIG. 4 is a configuration diagram of a different example system used for implementing a method according to an embodiment of the present invention.

FIG. 5 is a flow chart showing operation of a system used for implementing a method according to an embodiment of the present invention.

FIG. 6 is a figure showing an example of maintenance information.

FIG. 7 is a figure showing an example of a timetable.

FIG. 8 is a figure showing an example of a method for calculating a throughput based on a timetable.

FIG. 9 is a flow chart showing operation of a system used for implementing a method according to a different embodiment of the present invention.

FIG. 10 is a figure showing examples of calculation of individual throughputs.

### DESCRIPTION OF EMBODIMENTS

In the following description, embodiments of the present invention will be explained with reference to the figures. In the figures which will be explained below, a reference symbol that is the same as that assigned to one component is assigned to the other component which is the same as or corresponds to the one component, and overlapping explanation of these components will be omitted.

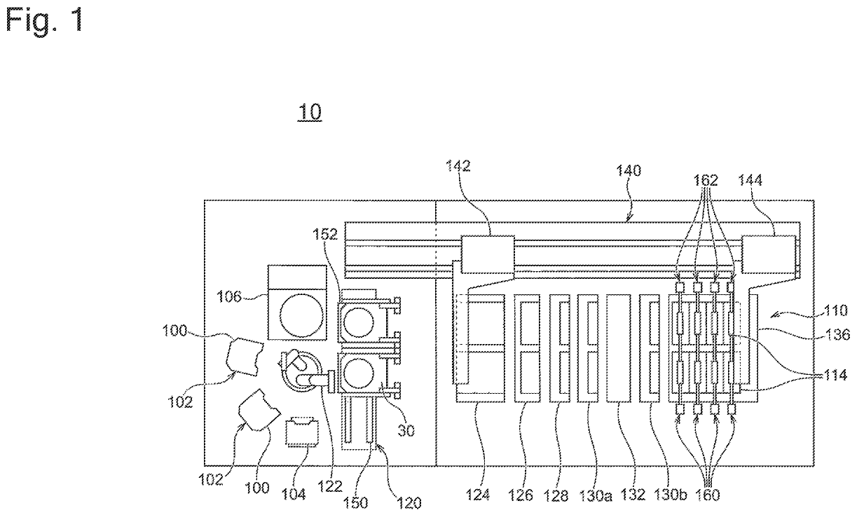

FIG. 1 is a general layout drawing of a plating apparatus 10 relating to an embodiment of the present invention. As shown in FIG. 1, the plating apparatus 10 comprises: two cassette tables 102; an aligner 104 for aligning, in a predetermined direction, a position of an orientation flat, a notch, or the like of a substrate; and a spin rinse dryer 106 for drying, after completion of a plating process of a substrate, the substrate by rotating it at high speed. A cassette 100, in which a substrate such as a semiconductor wafer or the like is housed, is loaded onto the cassette table 102. A load/unload station 120, onto which a substrate holder 30 is loaded to attach/detach a substrate thereto/therefrom, is installed in a position close to the spin rinse dryer 106. In a position in the center of the above units 100, 104, 106, and 120, a transfer robot 122 which carries a substrate between the above units is arranged.

The load/unload station 120 comprises loading plates 152, wherein each loading plate 152 has a flat plate shape and is able to slide in a lateral direction along rails 150. Two substrate holders 30 are loaded, in parallel with each other in a horizontal state, onto the loading plates 152; and, after completion of delivery of a substrate between one of the substrate holders 30 and the transfer robot 122, the loading plates 152 are slid in a lateral direction, and delivery of a substrate between the other of the substrate holders 30 and the transfer robot 122 is performed.

The plating apparatus 10 further comprises a stocker 124, a pre-wet module 126, a pre-soak module 128, a first rinse module 130a, a blow module 132, a second rinse module 130b, and a plating module 110. In the stocker 124, storing and temporary storing of a substrate holder 30 is performed. In the pre-wet module 126, a substrate is soaked in pure water. In the pre-soak module 128, an oxide film on a surface of an electrically conducting layer such as a seed layer or the like formed on a surface of a substrate is removed by etching. In the first rinse module 130a, a substrate is rinsed together with a substrate holder 30 by using a cleaning solution (pure water or the like) after pre-soaking. In the blow module 132, liquid removal of a substrate is performed after rinsing. In the second rinse module 130b, a plated substrate is rinsed together with a substrate holder 30 by using a cleaning solution. The load/unload station 120, the stocker 124, the pre-wet module 126, the pre-soak module 128, the first rinse module 130a, the blow module 132, the second rinse module 130b, and the plating module 110 are arranged in the above listed order.

For example, the plating module 110 is constructed in such a manner that plural plating tanks 114 are housed in the inside of an overflow tank 136. In the example of FIG. 1, the plating module 110 comprises eight plating tanks 114. Each plating tank 114 is constructed in such a manner that it receives a single substrate in the inside thereof, soaks the substrate in plating liquid held in the inside thereof, and applies plating such as copper plating or the like to a surface of the substrate.

The plating apparatus 10 comprises a transfer apparatus 140 which is arranged in a position on a side of the above respective devices, adopts, for example, a linear motor system, and conveys a substrate holder 30, together with a substrate, between the above respective devices. The transfer apparatus 140 comprises a first transfer apparatus 142 and a second transfer apparatus 144. The first transfer apparatus 142 is constructed to convey a substrate between the load/unload station 120, the stocker 124, the pre-wet module 126, the pre-soak module 128, the first rinse module 130a, and the blow module 132. The second transfer apparatus 144 is constructed to convey a substrate between the first rinse module 130a, the second rinse module 130b, the blow module 132, and the plating module 110. The plating apparatus 10 may be constructed in such a manner that it does not comprise the second transfer apparatus 144, i.e., it comprises the first transfer apparatus 142 only.

In positions on both sides of the overflow tank 136, paddle drivers 160 and paddle followers 162 are arranged, wherein each of the paddle drivers 160 and each of the paddle followers 162 drive a paddle which is arranged in each of the plating tanks 114 and works as a stirring rod for stirring plating liquid in the plating tank 114.

An example of a series of plating processes performed by the plating apparatus 10 will be explained. First, a substrate is taken out by the transfer robot 122 from the cassette 100 loaded on the cassette table 102, and the substrate is conveyed to the aligner 104. The aligner 104 aligns, in a predetermined direction, a position of an orientation flat, a notch, or the like. The substrate, that has been aligned with respect to the direction by the aligner 104, is conveyed by the transfer robot 122 to the load/unload station 120.

Regarding the load/unload station 120, two substrate holders 30, which have been stored in the stocker 124, are gripped at the same time by the first transfer apparatus 142 in the transfer apparatus 140, and conveyed to the load/unload station 120. Thereafter, the two substrate holders 30 are put, at the same time and horizontally, on the loading plates 152 in the load/unload station 120. In the above state, the transfer robot 122 conveys the substrates to the substrate holders 30, respectively, and the conveyed substrates are held in the substrate holders 30, respectively.

Next, the two substrate holders 30, which hold the substrates, are gripped at the same time by the first transfer apparatus 142 in the transfer apparatus 140, and housed in the pre-wet module 126. Next, the substrate holders 30, which hold the substrates processed in the pre-wet module 126, are conveyed to the pre-soak module 128 by the first transfer apparatus 142, and, in the pre-soak module 128, an etching process is applied to an oxide film on each of the substrates. Following thereto, the substrate holders 30, which hold the above substrates, are conveyed to the first rinse module 130a, and the surfaces of the substrates are rinsed by pure water stored in the first rinse module 130a.

The substrate holders 30, which hold the substrates with respect to which the rinsing process applied thereto has been completed, are conveyed from the first rinse module 130a to the plating module 110 by the second transfer apparatus 144, and housed in the plating tanks 114 which have been filled with plating liquid. The second transfer apparatus 144 repeats the above procedures sequentially to thereby sequentially house the substrate holders 30, which hold substrates, in the plating tanks 114 in the plating module 110, respectively.

In each of the plating tanks 114, a surface of the substrate is plated by supplying plating electric current between the substrate and an anode (not shown in the figure) in the plating tank 114, and, at the same time, moving the paddle forward and backward, in parallel with the surface of the substrate, by the paddle driver 160 and the paddle follower 162.

After completion of plating, two substrate holders 30, which hold the plated substrates, are gripped at the same time by the second transfer apparatus 144, and conveyed to the second rinse module 130b, and the surfaces of the substrates are rinsed by pure water by soaking them in the pure water stored in the second rinse module 130b. Next, the substrate holders 30 are conveyed to the blow module 132 by the second transfer apparatus 144, and water droplets remaining on the substrate holders 30 are removed by air-blowing or the like. Thereafter, the substrate holders 30 are conveyed to the load/unload station 120 by the first transfer apparatus 142.

In the load/unload station 120, the processed substrate is taken out from the substrate holder 30 by the transfer robot 122, and conveyed to the spin rinse dryer 106. The spin rinse dryer 106 rotates, at high speed, the plated substrate to thereby dry it. The dried substrate is returned to the cassette 100 by the transfer robot 122.

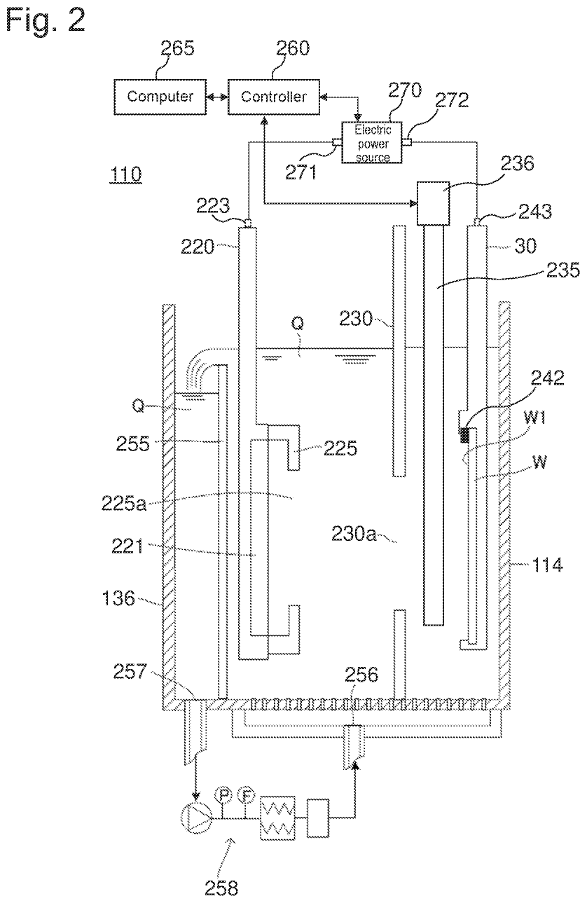

FIG. 2 is a schematic cross-sectional side view of the above-explained plating module 110. As shown in the figure, the plating module 110 comprises an anode holder 220 which is constructed to hold an anode 221, the substrate holder 30 which is constructed to hold a substrate W, the plating tank 114 which stores plating liquid Q including an additive, and an overflow tank 136 which receives and discharges a quantity of plating liquid Q overflowed from the plating tank 114. The plating tank 114 and the overflow tank 136 are separated from each other by a partition wall 255. The anode holder 220 and the substrate holder 30 are housed in the inside of the plating tank 114. As explained above, the substrate holder 30 holding the substrate W is conveyed by the second transfer device 144 (refer to FIG. 1) and housed in the plating tank 114.

In this regard, although a single plating tank 114 only is drawn in FIG. 2, the plating module 110 may be that comprising plural plating tanks 114 as explained above, wherein each plating tank comprises the construction shown in FIG. 2.

The anode 221 is electrically connected to a positive terminal 271 of an electric power source 270 via an electric terminal 223 installed on the anode holder 220. The substrate W is electrically connected to a negative terminal 272 of the electric power source 270, via an electric contact 242 which is in contact with a periphery of the substrate W and an electric terminal 243 installed on the substrate holder 30. The electric power source 270 is constructed in such a manner that it supplies plating electric current between the anode 221 connected to the positive terminal 271 and the substrate W connected to the negative terminal 272, and also measures a voltage applied between the positive terminal 271 and the negative terminal 272.

Further, the electric power source 270 is connected to a controller 260 which controls operation of the electric power source 270, and the controller 260 is connected to a computer 265. The computer 265 provides a user interface for an operator of the plating apparatus 10. The operator of the plating apparatus 10 can input, via the computer 265, various kinds of setting information relating to plating processes. For example, the setting information includes a set value of plating electric current outputted from the electric power source 270. The controller 260 makes the electric power source 270 operate in accordance with a plating-electric-current set value inputted by the operator. Further, the controller 260 provides the computer 256 with status information that is based on information of a voltage that is applied between the terminals 271 and 272 and measured by the electric power source 270. The operator of the plating apparatus 10 can receive the status information via the computer 265. The controller 260 may be constructed in such a manner that it controls operation of respective parts other than the electric power source 270 in the plating module 110, or respective units other than the plating module 110 in the plating apparatus 10, and provides the computer 265 with various kinds of status information relating to above operation.

The anode holder 220 holding the anode 221 and the substrate holder 30 holding the substrate W are soaked in the plating liquid Q in the plating tank 114, and arranged to face with each other in such a manner that the anode 220 and the to-be-plated surface W1 of the substrate W are positioned in virtually parallel with each other. In the state that the anode 221 and the substrate W are being soaked in the plating liquid Q in the plating tank 114, the plating electric current is supplied from the electric power source 270 to them. As a result, metal ions in the plating liquid Q are deoxidized on the to-be-plated surface W1 of the substrate W, and a film is formed on the to-be-plated surface W1.

The anode holder 220 comprises an anode mask 225 for adjusting an electric field between the anode 221 and the substrate W. The anode mask 225 is a member which is virtually tabular and comprises dielectric material, for example, and installed on a front surface side of the anode holder 220 (a surface on a side facing the substrate holder 30). That is, the anode mask 225 is positioned between the anode 221 and the substrate holder 30. The anode mask 225 comprises a first opening 225a, through which the electric current flowing between the anode 221 and the substrate W passes. It is preferable that the diameter of the opening 225a be smaller than the diameter of the anode 221. The anode mask 225 may be constructed in such a manner that the diameter of the opening 225a is adjustable.

The plating module 110 further comprises a regulation plate 230 for adjusting the electric field between the anode 221 and the substrate W. The regulation plate 230 is a member which is virtually tabular and comprises dielectric material, for example, and arranged in a position between the anode mask 225 and the substrate holder 30 (the substrate W). The regulation plate 230 comprises a second opening 230a, through which the electric current flowing between the anode 221 and the substrate W passes. It is preferable that the diameter of the opening 230a be smaller than the diameter of the substrate W. The regulation plate 230 may be constructed in such a manner that the diameter of the opening 230a is adjustable.

A paddle 235 is arranged in a position between the regulation plate 230 and the substrate W, for stirring the plating liquid Q existing in a region near the to-be-plated surface W1 of the substrate W. The paddle 235 is a member having a virtually rod shape, and arranged in the plating tank 114 in such a manner that it extends in a vertical direction. One of ends of the paddle 235 is fixed to the paddle driving device 236. Operation of the paddle driving device 236 is controlled by the controller 260, and the paddle 235 is moved horizontally by the paddle driving device 236 in a direction along the to-be-plated surface W1 of the substrate W. The plating liquid Q is stirred thereby.

The plating tank 114 comprises a plating liquid supply port 256 for supplying the plating liquid Q to the inside of the tank. The overflow tank 136 comprises a plating liquid exhaust port 257 for discharging a quantity of plating liquid Q overflowed from the plating tank 114. The plating liquid supply port 256 is arranged in a position on the bottom of the plating tank 114, and the plating liquid exhaust port 257 is arranged in a position on the bottom of the overflow tank 136.

When the plating liquid Q is being supplied from the plating liquid supply port 256 to the plating tank 114, a quantity of plating liquid Q overflows from the plating tank 114, and flows into the overflow tank 136 over the partition wall 255. The plating liquid Q flown into the overflow tank 136 is discharged from the plating liquid exhaust port 257, and impurities therein are removed by a filter or the like included in a plating liquid circulating device 258. The plating liquid Q, from which the impurities have been removed, is supplied to the plating tank 114 by the plating liquid circulating device 258 via the plating liquid supply port 256.

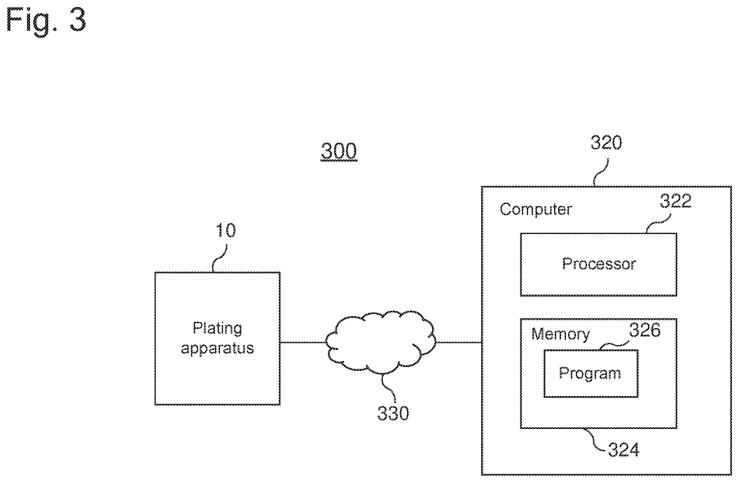

FIG. 3 is a configuration diagram of an example system 300 used for implementing a method according to an embodiment of the present invention. The system 300 comprises a plating apparatus 10 and a computer 320. The plating apparatus 10 is the plating apparatus which was explained with reference to FIG. 1 or 2. The plating apparatus 10 and the computer 320 are communicably connected with each other via a network 330 such as a LAN (local area network), the Internet, or the like. In a different construction, the computer 320 may be incorporated in the plating apparatus 10 as a part of the construction of the plating apparatus 10. The computer 320 comprises a processor 322 and a memory 324. The memory 324 stores a program 326 which realizes a method according to an embodiment of the present invention. The processor 322 reads the program 326 from the memory 324 and executes it. As a result, the system 300 is made to be able to implement the method according to an embodiment of the present invention.

In this regard, although a single computer 320 only is shown in FIG. 3, the system 300 may comprise plural computers 320. In the case of the above construction, memories 324 in the computers 320 may store programs corresponding to parts of the method according to an embodiment of the present invention, respectively; and the processors 322 in the computers 320 may execute the programs, respectively, in such a manner that plural computers 320 cooperate with one another to implement, as a whole, the method according to an embodiment of the present invention.

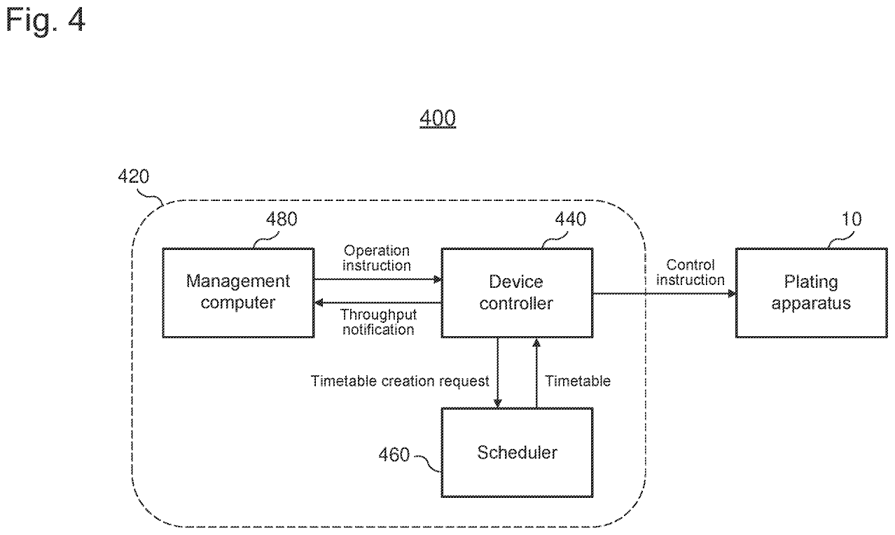

FIG. 4 is a configuration diagram of a different example system 400 used for implementing a method according to an embodiment of the present invention. The system 400 comprises a plating apparatus 10 and a group of computers 420. The system 400 comprises the group of computers 420 comprising a device controller 440, a scheduler 460, and a management computer 480. That is, the system shown in FIG. 4 corresponds to an example in the case that the system 300 in FIG. 3 comprises plural computers. Each of the device controller 440, the scheduler 460, and the management computer 480 comprises a processor and a memory similar to those in the computer 320 in the system 300 shown in FIG. 3. In the system 400, the plating apparatus 10, the device controller 440, the scheduler 460, and the management computer 480 are connected with one another via communication paths. In a different construction, a part(s) or the whole of the device controller 440, the scheduler 460, and the management computer 480 is/are incorporated in the plating apparatus 10 as a part of the construction of the plating apparatus 10.

In the system 400 in FIG. 4, the management computer 480 receives operation instructions of the plating apparatus 10 from an operator of the system 400 (for example, receives data input via a user interface), and supplies the operation instructions to the device controller 440. The operation instructions (hereinafter, this is also referred to as a “process parameter”) comprises various kinds of parameters for designating conditions of a paltering process in the plating apparatus 10, various kinds of setting values for respective parts in the plating apparatus 10, and/or designation information relating to control of operation of the plating apparatus 10, and so on.

The device controller 440 transmits a request for creation of a timetable to the scheduler 460, and, in response thereto, the scheduler 460 creates a timetable and supplies it to the device controller 440. The timetable creation request is transmitted from the device controller 440 to the scheduler 460 in accordance with operation instructions from the management computer 480.

The device controller 440 calculates, based on the timetable, a throughput of the plating apparatus 10. Further, the device controller 440 transmits, in accordance with the timetable, control instructions to the plating apparatus 10 for controlling respective parts of the plating apparatus 10. Information of the throughput calculated by the device controller 440 is communicated to the management computer 480, and displayed by the display device in the management computer 480.

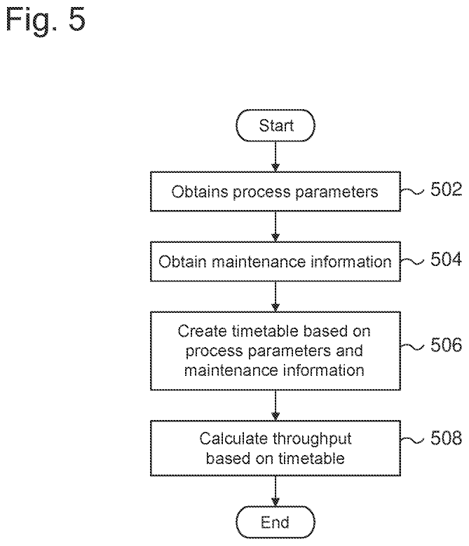

FIG. 5 is a flow chart showing operation of the system 300 or 400 used for implementing a method according to an embodiment of the present invention. The processes in the respective steps in the flow chart in FIG. 5 are performed by a processor(s). In the following explanation, unless otherwise specified, the “processor” refers to the processor 322 in the computer 320 shown in FIG. 3, or any of appropriate processors in the device controller 440, the scheduler 460, and the management computer 480 shown in FIG. 4. The method according to the embodiment in FIG. 5 starts from step 502.

It should be reminded with respect to the following description that the term “unit(s)” means any one or plural modules in the pre-wet module 126, the pre-soak module 128, the first rinse module 130a, the second rinse module 130b, and the plating module 110. Further, each unit comprises a single or plural tanks. For example, the plating module 110 comprises four tanks having constructions similar to one another, and the tanks can apply same processes to substrates, respectively. That is, the plating module 110 can process at most four substrates at the same time in parallel by using the four tanks at the same time. The above matter also applies to the units other than the plating module 110. In this regard, the unit(s) may include, in addition to those listed above, the blow module 132, the aligner 104, the spin rinse dryer 106, the load/unload station 120, and so on.

In step 502, the processor obtains process parameters relating to processes applied to a substrate in the plating apparatus 10. For example, the processor in the device controller 440 obtains, from the management computer 480, process parameters inputted to the management computer 480 by the operator of the system 400. Examples of process parameters are shown below.
(1) Setting information of the plating apparatus
   The number of substrate holders
   The number of tanks in each unit
   Designation, with respect to each of tanks in each unit, for designating whether or not the tank is to be used (For example, designation to set the plating module 110 in such a manner that the first to third tanks are to be used and the fourth tank are not to be used, in the case that the plating module 110 comprises four tanks, or the like)
(2) Setting information of each unit
   Operation time of movable structures
   Pre-processing/post-processing time
   Reset time
(3) Setting information of transfer apparatuses
   Time of movement between respective units
   Operation time for storing a substrate in each unit
   Operation time for taking out a substrate from each unit
(4) Recipe information
   The order of respective processes performed in respective units
   Time of processing in each unit
   The number of substrates which are to be processed
(5) Constraint conditions
   Time during that a substrate is allowed to be left in a tank in each unit after completion of a process therein
   Restriction relating to substrate transfer for avoiding collision/interference between plural transfer apparatuses (the first transfer apparatus 142 and the second transfer apparatus 144).

Next, in step 504, the processor obtains maintenance information. For example, maintenance information relating to respective units in the plating apparatus 10 has been stored in advance in the memory in the device controller 440, and the processor in the device controller 440 obtains the maintenance information from the memory. The maintenance information is information of timing of maintenance of each of tanks in each unit and the length of time required for the maintenance, wherein the maintenance is that planned to be performed in a period that has a predetermined length and ends when processing of plural substrates in the plating apparatus 10 is completed. In this regard, it is supposed that maintenance includes repair, adjustment, inspection, replacement of components, and so on performed in relation to the unit and/or the tank.

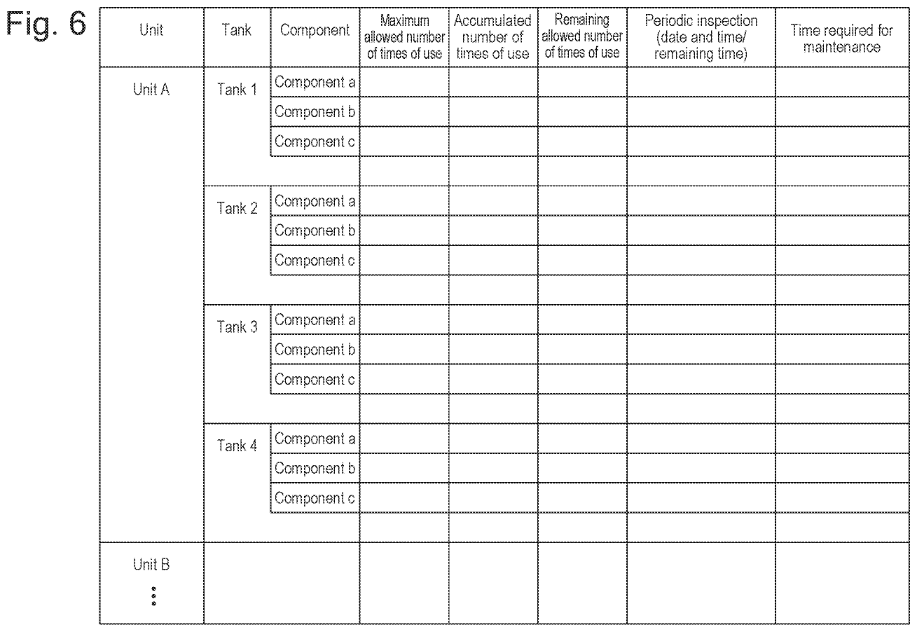

FIG. 6 is a figure showing an example of maintenance information. In the example in FIG. 6, a unit A comprises tanks 1-4, and each of the tanks comprises a component a, a component b, and a component c. With respect to each of the component a, the component b, and the component c, the maximum allowable number of times of use, that the component is allowed to be used, has been set. Each of the components is not allowed to be used after the number of times that the component was used has reached the maximum allowable number of times of use, and replacement of the component has to be performed after the number of times that the component was used has reached the maximum allowable number of times of use. Regarding each of components in each tank, the accumulated number of times of use, that the component was used up to the present time, and the remaining allowable number of times of use are also recorded as part of the maintenance information. The remaining allowable number of times of use is the number of times that is obtained by subtracting the accumulated number of times of use of a component from the maximum allowable number of times of use of the component. Thus, the remaining allowable number of times of use can be used as a reference when determining timing of next maintenance of the unit. Further, the maintenance information includes a schedule of periodic inspection (or periodic repair or adjustment) with respect to each tank. The schedule of periodic inspection may be information of date and time when next inspection of the tank should be performed, or information of remaining time until the time when next inspection of the tank is to be performed. Further, regarding maintenance work such as replacement of components, inspection of units, and so on, the length of time that is expected to be required for maintenance work (an expected length of time from the time of a start to the time of an end of the work) has been set with respect to each kind of maintenance. As explained above, the maintenance information comprises, with respect to each unit, information relating to timing when maintenance should be performed and time required for the maintenance. With respect to each of tanks in each unit, maintenance work of the tank is performed when the time for performing maintenance, that has been scheduled, has come, and the tank is disallowed to be used during the maintenance work.

The maintenance information is updated and held at any time in association with progress in processing of a substrate in the plating apparatus 10. For example, when a component is used in a tank in a unit, the processor in the device controller 440 reduces the accumulated number of times of use of the component by the number of times that the component was used, and correspondingly updates the remaining allowable number of times of use of the component. Also, if a tank in a unit was used for a length of time, the processor in the device controller 440 updates the remaining time included in the maintenance information, i.e., the remaining time until the time when next inspection of the tank is to be performed, by subtracting the above length of time from the remaining time.

Next, FIG. 5 is referred to again, and, in step 506, the processor creates a timetable based on the process parameters obtained in step 502 and the maintenance information obtained in step 504. The timetable is information representing an operation schedule including information such as when each of units in the plating apparatus 10 will be operated to perform a process, to which substrate the process will be applied, and what kind of process the unit will perform. For example, the processor in the device controller 440 transmits, to the scheduler 460, the process parameters, the maintenance information, and a timetable creation request that instructs the scheduler 460 to create a timetable based on the process parameters and the maintenance information; and, in response thereto, the processor in the scheduler 460 creates the timetable.

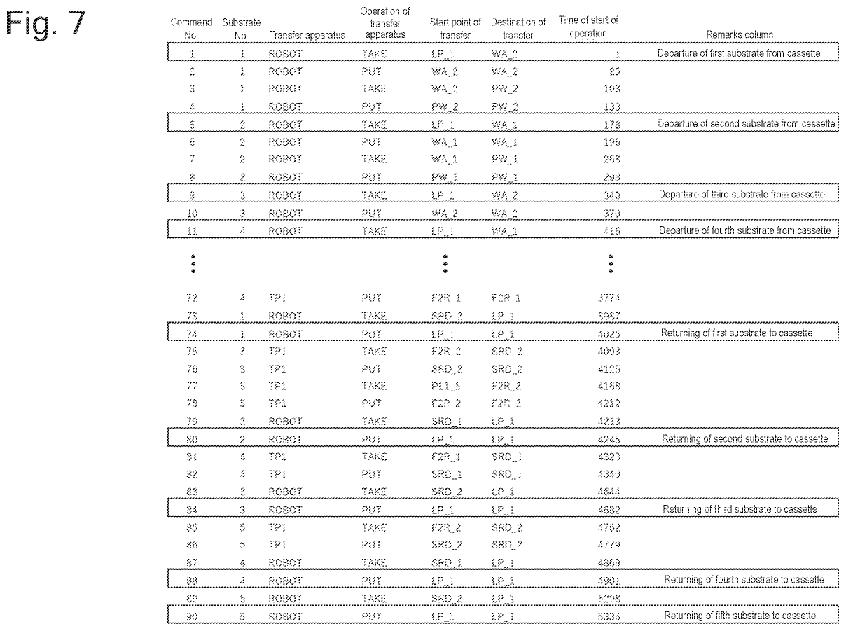

FIG. 7 is a figure showing an example of a timetable. In the example, each of the rows in the table corresponds to operation of one of the transfer apparatuses (the transfer robot 122, the first transfer apparatus 142, and the second transfer apparatus 144 in the plating apparatus 10 in FIG. 1). Specifically, each row represents designation of a transfer apparatus that is to be operated, timing when the transfer apparatus is to be operated, a substrate which is to be conveyed, a unit from which the substrate is to be conveyed, and a unit to which the substrate is to be conveyed. It should be reminded that, for making it easier to understand the construction in FIG. 7, each of the rows relating to operation for moving a substrate to leave the cassette 100 and each of the rows relating to operation for moving a substrate to return to the cassette 100 in the plating apparatus 10 are enclosed in frames (Refer to the remarks column in FIG. 7. In this regard, it may not be necessary to include a remarks column in a timetable.).

In this regard, it should be reminded that the time table created in step 506 (for example, the timetable illustrated in FIG. 7) is that reflecting the maintenance information of respective units in the plating apparatus 10. Specifically, regarding a tank in a unit which is included as an object of maintenance in the maintenance information, the timetable is created in such a manner that the tank is not used during the time when maintenance thereof is being performed. Thus, for example, if it is scheduled to perform maintenance of a tank after completion of processing of a substrate (for example, the (k)th substrate), completion of processing of a substrate (the (k+1)th substrate), that is in the middle of processing, may be delayed than completion of processing in the case that the timetable is created without taking the maintenance information into consideration. That is, the throughput may be lowered as a result of performing of maintenance. The timetable, that is created in step 506 and is based on the maintenance information, represents respective operation schedules of respective units including influence of maintenance such as that explained above.

Next, FIG. 5 is referred to again, and, in step 508, the processor calculates the throughput of the plating apparatus 10, based on the timetable created in step 506. The throughput of the plating apparatus 10 is an index representing processing capacity per unit time of the plating apparatus 10, and, for example, may be defined as the number of substrates which can be produced by the plating apparatus 10 (i.e., the number of substrates, with respect to each of which all processing steps in a series of processing steps performed in the plating apparatus 10 have been completed) per unit time.

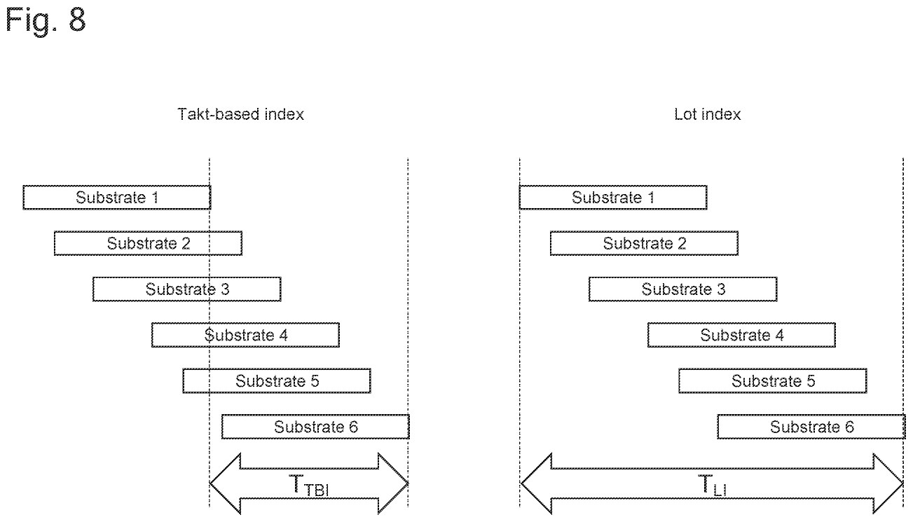

FIG. 8 is a figure showing an example of a method for calculating a throughput based on a timetable. With respect to each of substrates 1-6, FIG. 8 depicts, in the form of a horizontal bar, a period from a point in time when the substrate leaves the cassette 100 to a point in time when the substrate returns to the cassette 100 in the plating apparatus 10. The left end of the bar corresponds to the time when the substrate leaves the cassette 100, and the right end of the bar corresponds to the time when the substrate returns to the cassette 100 (refer to the rows enclosed in frames in the timetable in FIG. 7). The respective substrates sequentially leave the cassette 100 in the order of the substrate 1, substrate 2, substrate 3, substrate 4, substrate 5, and substrate 6, wherein the time when each substrate leaves the cassette 100 is different from the time when other substrates leave the cassette 100; the substrates are processed by respective units in the plating apparatus 10; and the substrates sequentially return to the cassette 100 in the order that is the same as the above order.

Regarding the method for calculating a throughput in the plating apparatus 10, there are calculation methods such as a calculation method using a takt-based index and a calculation method using a lot index. As shown in FIG. 8, the throughput based on the lot index is calculated in the manner shown below in the form of formula (1) that is based on the length of time (T_{LI} in the figure) from the time when the first substrate (the substrate 1) leaves the cassette 100 to the time when the last substrate (the substrate 6) returns to the cassette 100. On the other hand, the throughput based on the takt-based index is calculated in the manner shown below in the form of formula (2) that is based on the length of time (T_{TBI} in the figure) from the time when the first substrate (the substrate 1) returns to the cassette 100 to the time when the last substrate (the substrate 6) returns to the cassette 100.

$$Throughput LI = N / {T}_{LI} \qquad ( 1 )$$

$$Throughput TBI = ( N - 1 ) / {T}_{TBI} \qquad ( 2 )$$

In this manner, according to the present embodiment, the throughput of the plating apparatus 10 is calculated based on the timetable which reflects the maintenance information. The maintenance information comprises timing of scheduled maintenance of each of units (each of tanks) in the plating apparatus 10 and the length of time required for the maintenance. Thus, it becomes possible to know an accurate throughput that is obtained by taking influence of maintenance in the plating apparatus 10 into consideration.

It should be reminded that step 502 in the flow chart in FIG. 5 may be that started, for example, when a first instruction for processing a predetermined number of substrates under a predetermined recipe condition in the plating apparatus 10 is inputted to the management computer 480, or when an instruction for additionally processing a predetermined number of substrates is inputted to the management computer 480 during the time when processing of a substrate is being performed in the plating apparatus 10. In this regard, in the latter case, in step 504 that follows step 502, the maintenance information, that has been updated in association with substrate processing that has been completed up to the present time, is obtained, and, in step 506, a timetable is created based on the updated maintenance information.

Further, step 504 in the flow chart in FIG. 5 (i.e., acquisition of maintenance information) may be performed, for example, by using, as a trigger to start the step, an event that an instruction for calculating the throughput of the plating apparatus 10 is inputted to the management computer 480 by the operator of the system 400. For example, the operator of the system 400 can instruct the system 400 to calculate the throughput by pressing a predetermined instruction button on a manipulation screen in the management computer 480 at any timing (for example, before starting of operation of the plating apparatus 10, or during processing of a substrate in the plating apparatus 10). In the case that an instruction such as that explained above is given during the time when a substrate is being processed in the plating apparatus 10, the maintenance information that has been updated in association with substrate processing that has been completed up to the present time is obtained in step 504, and a timetable is created based on the updated maintenance information in step 506, in a manner similar to that explained above.

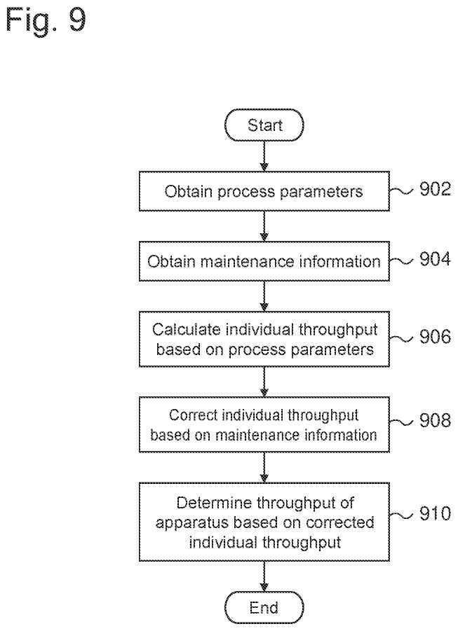

FIG. 9 is a flow chart showing operation of the system 300 or 400 used for implementing a method according to a different embodiment of the present invention. Steps 902 and 904 in FIG. 9 are the same as steps 502 and 504 in the flow chart in above-explained FIG. 5, respectively, and repeated explanation thereof will be omitted herein. In the following description, step 906 and steps following thereto will be explained.

In step 906, the processor calculates, based on process parameters obtained in step 902, individual throughputs of respective units in the plating apparatus 10. The individual throughput is throughput of each of the units, and may be defined as the number of substrates which can be processed by a single unit per unit time.

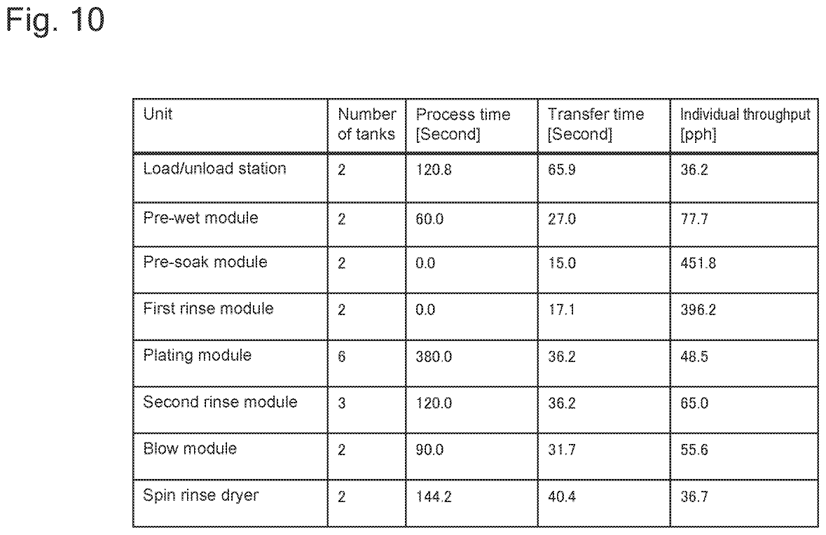

FIG. 10 is a figure showing examples of calculation of individual throughputs. In this example, the individual throughput of each of units is calculated by using the number of tanks n included in the unit, process time T1 that is required for processing a single substrate in the unit, and transfer time T2 that is required for conveying a single specific substrate between the unit and a different unit by a transfer apparatus. Information of the number of tanks n, the process time T1, and the transfer time T2 is included in the process parameters obtained in step 902. For example, the individual throughput of each unit can be calculated in the manner shown in the form of formula (3) below.

$$Individual throughput = n / ( T 1 + T 2 ) \qquad ( 3 )$$

Next, in step 908, the processor corrects, based on the maintenance information obtained in step 904, the individual throughput of each unit. Specifically, with respect to a unit which is included as an object of maintenance in the maintenance information, the individual throughput is corrected by subtracting the number of tanks which are objects of maintenance from the number of tanks n in the unit, and recalculating the individual throughput by using above formula (3). For example, in the case that the plating module 110 comprises four tanks and one of the tanks is an object of maintenance, n is set to 3 in above formula (3) and the individual throughput of the plating module 110 is recalculated.

Next, in step 910, the processor determines the throughput of the plating apparatus 10 based on the corrected individual throughputs. For example, the smallest individual throughput among the respective individual throughputs of the respective units is determined as the throughput of the plating apparatus 10.

As explained above, according to the present embodiment, the individual throughout of each unit is corrected to reflect the maintenance information, and the throughput of the plating apparatus 10 is calculated thereby. Thus, it becomes possible to know accurate throughout, that is obtained by taking influence of maintenance into consideration, of the plating apparatus 10. In this regard, in the above-explained embodiment, since the timetable representing rigorous operation schedules of respective units is used, the throughput of the plating apparatus 10 can be calculated more accurately; on the other hand, in the present embodiment, since individual throughputs that can be calculated by using a simple formula is used, the present embodiment may be used preferably when it is desired to obtain the throughput of the plating apparatus 10 in a simple manner.

It should be reminded that step 902 in the flow chart in FIG. 9 may be that started, for example, in a manner similar to that in the case of the flow chart in FIG. 5, i.e., started when a first instruction for processing a predetermined number of substrates under a predetermined recipe condition in the plating apparatus 10 is inputted to the management computer 480, or when an instruction for additionally processing a predetermined number of substrates is inputted to the management computer 480 during the time when processing of a substrate is being performed in the plating apparatus 10. In this regard, in the latter case, in step 904 that follows step 902, the maintenance information, that has been updated in association with substrate processing that has been completed up to the present time, is obtained, and, in step 908, correction of the individual throughputs by using the updated maintenance information is performed.

Further, step 904 in the flow chart in FIG. 9 (i.e., acquisition of maintenance information) may be performed, for example, by using, as a trigger to start the step, an event that an instruction for calculating the throughput of the plating apparatus 10 is inputted to the management computer 480 by the operator of the system 400. For example, the operator of the system 400 can instruct the system 400 to calculate the throughput by pressing a predetermined instruction button on a manipulation screen in the management computer 480 at any timing (for example, before starting of operation of the plating apparatus 10, or during processing of a substrate in the plating apparatus 10). In the case that an instruction such as that explained above is given during the time when a substrate is being processed in the plating apparatus 10, the maintenance information that has been updated in association with substrate processing that has been completed up to the present time is obtained in step 904, and correction of the individual throughputs by using the updated maintenance information is performed in step 908, in a manner similar to that explained above.

In the above description, embodiments of the present invention have been explained based on some examples; and, in this regard, the above explained embodiments of the present invention are those used for facilitating understanding of the present invention, and are not those used for limiting the present invention. It is obvious that the present invention can be changed or modified without departing from the scope of the gist thereof, and that the present invention includes equivalents thereof. Further, it is possible to arbitrarily combine components or omit a component(s) disclosed in the claims and the specification, within the scope that at least part of the above-stated problems can be solved or within the scope that at least part of advantageous effect can be obtained.

### REFERENCE SIGNS LIST

10 Plating apparatus
30 Substrate holder
100 Cassette
102 Cassette table
104 Aligner
106 Spin rinse dryer
110 Plating module
114 Plating tank
120 Load/unload station
122 Transfer robot
124 Stocker
126 Pre-wet module
128 Pre-soak module
130a First rinse module
130b Second rinse module
132 Blow module
136 Overflow tank
140 Transfer apparatus
142 First transfer apparatus
144 Second transfer apparatus
150 Rail
152 Loading plate
160 Paddle driver
162 Paddle follower
300 System
320 Computer
322 Processor
324 Memory
326 Program
330 Network
400 System
420 Group of computers
440 Device controller
460 Scheduler
480 Management computer

What is claimed is:

1. A method for calculating a throughput in a semiconductor manufacturing apparatus, which comprises plural units, comprising steps for:
obtaining a process parameter relating to processing of a substrate in the semiconductor manufacturing apparatus;
obtaining, from a memory, maintenance information with respect to each unit in the plural units, wherein the maintenance information comprises timing of maintenance of each unit in the plural units and the length of time required for the maintenance, wherein the maintenance is that planned to be performed in a period that ends when processing of the substrate in the semiconductor manufacturing apparatus is completed; and
calculating a throughput of the semiconductor manufacturing apparatus, based on the process parameter and the maintenance information.

2. The method as recited in claim 1, wherein the step for calculating a throughput of the semiconductor manufacturing apparatus comprises steps for:
creating, based on the process parameter and the maintenance information, a timetable showing an operation schedule of the plural units; and
calculating, based on the timetable, a throughput of the semiconductor manufacturing apparatus.

3. The method as recited in claim 2 further comprising a step for updating, in association with progress in processing of the substrate in the semiconductor manufacturing apparatus, the maintenance information stored in the memory, wherein
creating of the timetable is performed in response to occurrence of a predetermined event and based on the updated maintenance information at the time of occurrence of the event.

4. The method as recited in claim 2, wherein creating of the timetable comprises determining the operation schedule in such a manner that each of all units included in the maintenance information as objects of maintenance is not used during maintenance thereof.

5. The method as recited in claim 1, wherein the step for calculating a throughput of the semiconductor manufacturing apparatus comprises steps for:
calculating, based on the process parameter, individual throughputs of the plural units;
correcting, based on the maintenance information, the individual throughputs; and
determining, based on the corrected individual throughputs, throughput of the semiconductor manufacturing apparatus.

6. The method as recited in claim 5 further comprising a step for updating, in association with progress in processing of the substrate in the semiconductor manufacturing apparatus, the maintenance information stored in the memory, wherein
correcting of the individual throughputs is performed in response to occurrence of a predetermined event and based on the updated maintenance information at the time of occurrence of the event.

7. The method as recited in claim 5, wherein correcting of the individual throughputs comprises correcting the individual throughputs according to a ratio between the number of units which are objects of maintenance and the number of units which are not objects of maintenance.

8. A semiconductor manufacturing apparatus comprising:
plural units;
a computer constructed to calculate the throughput according to the method recited in claim 1; and
a display device for displaying the calculated throughput.

9. A computer program product comprising computer executable instructions constructed to make a computer implement the method recited in claim 1 when the computer executable instructions are executed by a processor in the computer.
